(19) United States
(12) Patent Application Publication
(10) Pub. No.: US 2010/0183266 A1
(43) Pub. Date: Jul. 22, 2010

(54) OPTICAL MODULE AND METHOD FOR MANUFACTURING THE SAME

(76) Inventors: Kazuya Shimoda, Tokyo (JP); Mitsuru Kurihara, Tokyo (JP); Keisuke Yamamoto, Tokyo (JP)

Correspondence Address: Mr. Jackson Chen, 6535 N. STATE HWY 161, IRVING, TX, 75039, US

(21) Appl. No.: 12/664,241

(22) PCT Filed: Jun. 13, 2008
(86) PCT No.: PCT/JP2008/060873

§ 371 Date: Dec. 11, 2009

(30) Foreign Application Priority Data
Jun. 14, 2007 (JP) 2007-157851

(51) Int. Cl. G02B 6/42; H01L 31/18

(52) U.S. Cl. 385/88; 29/834

(57) ABSTRACT

A light receiving element (12) is mounted on a wiring board (9) with a first opening (10) formed on the wiring board (9) being aligned with a light receiving region (13). Two second openings (11) formed in the same process as used for the first opening (10) are provided on the wiring board (9). An optical waveguide having a core (3) of the optical waveguide, and two board marks having cores (5) of dummy optical waveguides are provided on an optical wiring board. At the time of optically coupling the light receiving region (13) and the core (3) of the optical waveguide, the openings (11) and the board marks are observed from the side of the light receiving element (12) on the wiring board (9) at the same time, and the wiring board (9) and the optical wiring board are aligned with each other based on the positions of the observed openings and board marks. This can ensure easy and highly accurate mounting assembly, and improve mass productivity.

### TECHNICAL FIELD

The present invention relates to an optical module which has optical elements, such as a light receiving element and a light emitting element, optically coupled to optical wirings, such as an optical waveguide and an optical fiber, and a method of manufacturing the optical module.

### BACKGROUND ART

Recently, there is a demand of downsizing an optical module for the purpose of improving the speed and reducing power consumption, which demands improvements on assembly precision of optical modules.

The configurations of optical modules according to related arts and manufacturing methods relating thereto are disclosed in, for example, Patent Literatures 1 and 2. Examples of related-art optical modules will be described below.

FIG. 10 is a perspective view showing the configuration of an optical module (first related art) described in Patent Literature 1. As shown in FIG. 10, in an optical module 101 according to the first related art, a package 120 including a light receiving/emitting element 102, and an optical waveguide board 103 including a signal core 104, a position regulating core 105, a board clad 131 and a cover clad 132 are provided on a base board 110. As an end portion of the signal core 104 formed at an end face 130 of the optical waveguide board 103 is arranged opposite to a light receiving/emitting part 121 of the light receiving/emitting element 102, the light receiving/emitting element 102 and the optical waveguide board 103 are optically coupled together. The optical waveguide board 103 has the position regulating core 105 whose end portion, apart from the end face of the signal core 104 by a predetermined distance, is arranged at the end face 130. An alignment mark 106 is arranged at the light receiving/emitting element 102 at a position opposite to the end portion of the position regulating core 105.

At the time of manufacturing the optical module 101, light irradiated on the alignment mark 106, and light reflected therefrom is measured through the position regulating core 105 at an other end P. According to this related art, the relative positions of the light receiving/emitting element 102 and the optical waveguide board 103 can be adjusted based on a change in the intensity of the measured reflected light.

FIG. 11 is a perspective view showing the configuration of a chip-part connecting apparatus (second related art) described in Patent Literature 2. While this related art is directed to a technique relating to a chip-part connecting apparatus, it can be adapted to a method of manufacturing an optical module as will be described below.

As shown in FIG. 11, the chip-part connecting apparatus according to this related art has a camera A 207, a camera B 208, and a camera C 210 which are used at the time of mounting a chip part 202 on a mount board 203. In FIG. 11, a mount stage (not shown) to which the mount board 203 is fixed is moved in a +y direction by an offset amount δy. At this time, the positions where the position of an image pattern 202a of the chip part 202 and the position of a positioning target 203c in a connecting surface 203b of the mount board 203 match with each other in connection with the x-axis direction and y-axis direction are respectively treated as reference positions of the chip part 202 and the mount board 203. At the reference positions, the images of the chip part 202 and the mount board 203 which are to be observed by the camera A 207, camera B 208 and camera C 210 are treated as reference images.

As the mount board 203 is imaged by the camera A 207 and the camera B 208, deviation amounts dbx and dby between the recognized images and the reference images are acquired. As the chip part 202 is imaged by the camera C 210, deviation amounts dhx and dhy between the recognized image and the reference images are acquired. The chip part 202 is mounted on the mount board 203 after its position is compensated by an amount calculated from those deviation amounts dbx, dby, dhx, dhy and the offset amount δy.

When the chip-part connecting apparatus according to the related art is adapted to the manufacture of an optical module, in FIG. 11, the chip part 202 becomes a wiring board, the image pattern 202a becomes a pin hole, the mount board 203 becomes an optical waveguide board, and the positioning target 203c becomes the input/output end of an optical waveguide. A wiring electrode is formed on the −z side of the wiring board (202), which is mounted in alignment with the pin hole (202a) in such a way that the light receiving/emitting surface of a light receiving/emitting element faces in the +z direction. The camera C210 faces in −z direction, disposed so that the position of camera 210 and the position indicated in the figure are symmetric about the wiring board (202). The light receiving/emitting area of the light receiving/emitting element, which is observed through the pin hole (202a) is registered as the image pattern of the wiring board (202). This configuration can ensure alignment of an optical module even when the second related art is adapted.

Patent Literature 1: Unexamined Japanese Patent Application KOKAI Publication No. 2005-134444

Patent Literature 2: Unexamined Japanese Patent Application KOKAI Publication No. 2003-243891

### DISCLOSURE OF INVENTION

However, the above-described related-art optical modules and methods of manufacturing the same have the following problems.

In the first related art, light is irradiated on the alignment mark 106, and its reflected light is measured at the other end P through the position regulating core 105. To make the measurement, it is necessary to align the alignment mark 106 with the optical axis of the irradiated light. It is also necessary to align the position regulating core 105 with the optical fiber or the like for measuring light. Those adjustments need setting of highly accurate and complicated apparatus and complicated parts. This makes the apparatus expensive and reduces the mass productivity.

In the second related art, the light receiving/emitting surface of the light receiving/emitting element and the input/output end of the optical waveguide of the optical waveguide board are recognized as image patterns and are aligned, and the faces of the recognized image patterns are connected to each other. Therefore, after the connection, the image patterns used for recognition are hid, so that misalignment cannot be measured. In the processes of alignment and connection, therefore, not only it is difficult to achieve high accuracy, but also it is not possible to correct misalignment, if occurred, causing defects.

In the optical module manufacturing method according to this related art, the positions at the pre-registered reference images are compared with the positions at the images recognized by the cameras to compensate the position of the wiring board 202 or the optical waveguide board 203. Because the positions or directions of the cameras change due to a change in the mechanical precision of the apparatus or the ambient temperature or the like, however, a change from the position at which the reference image is registered affects the positional compensation as a recognition error. Further, because misalignment cannot be measured due to the foregoing reasons, it is difficult to find a recognition error. Therefore, this not only makes it difficult to achieve high accuracy, but also causes defects.

The present invention addresses the problems, and it is an object of the invention to provide an optical module which can be mounted and assembled easily with a high accuracy and is excellent in mass productivity, and a method of manufacturing the same.

### Means for Solving the Problems

An optical module according to the present invention includes an electric wiring board on which an optical path is formed, an optical element mounted on the electric wiring board, and an optical wiring board having an optical wiring optically coupled to the optical element via the optical path, wherein the electric wiring board has a plurality of first positioning shapes for specifying a position of the optical path, the optical wiring board has a plurality of second positioning shapes for specifying a position of an end portion of the optical wiring, and the first and second positioning shapes are observable at the same time.

In this case, the first positioning shapes may be structured to include a projection, a recess, a through hole, an opening or a mark formed on the electric wiring board, and the electric wiring board, having the opening formed thereon can be structured to have a light transmitting base material. In addition, the optical path may have a through hole or an opening that is different from the first positioning shapes and formed in the same process as the process that forms the first positioning shapes. Further, the second positioning shapes may be structured to be observable through the through hole or the opening constituting the first positioning shapes from a side of the optical element on the electric wiring board.

The second positioning shapes may be structured to include a projection, a recess, a through hole, an opening or a mark formed on the optical wiring board, and the optical wiring may have a projection, a recess or a through hole formed in the same process as forms the second positioning shapes and different from that of the second positioning shapes. In this case, the projection of the second positioning shapes may be structured to be a dummy optical waveguide, and the projection of the optical wiring may be structured to be an optical waveguide for a signal. In addition, the recess of the second positioning shapes may be structured to be a positioning V-shaped groove, and the recess of the optical wiring may be structured to be a V-shaped groove for an optical fiber for fixing an optical fiber.

Further, the optical element may be a light receiving element or a light emitting element.

A method of manufacturing an optical module according to the present invention includes the steps of mounting an optical element on an electric wiring board in alignment with an optical path formed on the electric wiring board, simultaneously observing a plurality of first positioning shapes formed on an electric wiring board and a plurality of second positioning shapes formed on the optical wiring board, with the optical wiring board having an optical wiring and the electric wiring board overlapping each other, calculating a position of the optical path from positions of the observed first positioning shapes, and calculating a position of an end portion of the optical wiring from positions of the second positioning shapes, and fixing the electric wiring board and the optical wiring board in alignment with each other based on the calculated position of the optical path and the calculated position of the end portion of the optical wiring in such a way as to optically couple the optical element and the optical wiring via the optical path.

In this case, the first positioning shapes may include a projection, a recess, a through hole, an opening or a mark formed on the electric wiring board, and the through hole or opening constituting the first positioning shapes, and a through hole or an opening constituting the optical path may be formed on the electric wiring board in the same process. In addition, the second positioning shapes may be observed through the through hole or the opening constituting the first positioning shapes from a side of the optical element on the electric wiring board.

The second positioning shapes may include a projection, a recess, a through hole, an opening or a mark formed on the optical wiring board, and the projection, recess or through hole constituting the second positioning shapes, and a projection, recess or through hole constituting the optical wiring may be formed on the optical wiring board in the same process. In addition, the projection of the second positioning shapes may be a dummy optical waveguide, and the projection of the optical wiring may be an optical waveguide for a signal. Further, the recess of the second positioning shapes may be a positioning V-shaped groove, and the recess of the optical wiring may be a V-shaped groove for an optical fiber for fixing an optical fiber.

Furthermore, the optical element may be a light receiving element, and the optical element and the optical path may be aligned with each other in such a way that a light receiving region of the optical element includes an entire cross-sectional area of the optical path; the optical element may be a light emitting element, and the optical element and the optical path may be aligned with each other in such a way that a cross-sectional area of the optical path includes an entire light emitting region of the optical element.

### Effect of the Invention

According to the invention, mounting and assembly of an optical module can be implemented easily and with high accuracy, thus providing an optical module excellent in mass productivity.

### BRIEF DESCRIPTION OF DRAWINGS

FIG. 1 is a cross-sectional view showing an optical coupling structure for coupling a waveguide and a light receiving element of an optical module according to a first embodiment of the invention, the cross-sectional view being cut at a plane passing the optical axis of the core of an optical waveguide.

FIG. 2 is a cross-sectional view of the optical module according to the first embodiment cut along line A-A in FIG. 1.

FIG. 3 is a cross-sectional view of the optical module according to the first embodiment cut along line B-B or line C-C in FIG. 1.

FIG. 4 is a diagram showing the electrode pattern of a wiring board of the optical module according to the first embodiment of the invention.

FIG. 5 is a side cross-sectional view of an optical waveguide board of the optical module according to the first embodiment on that side where the wiring board is fixed.

FIG. 6 is a diagram showing how to align the optical waveguide of the optical module according to the first embodiment of the invention with the light receiving element.

FIG. 7 is a cross-sectional view showing an optical module according to a second embodiment of the invention, cut at a plane passing the optical axis of the core of an optical waveguide.

FIG. 8 is a cross-sectional view showing an optical waveguide board of an optical module according to a third embodiment of the invention in an example where the optical waveguide board is adapted to coupling of an optical fiber and a light receiving element.

FIG. 9 is a cross-sectional view showing an optical module according to a fourth embodiment of the invention, cut at a plane passing the optical axis of a light emitting element.

FIG. 10 is a diagram showing the configuration of the first related art described in Patent Literature 1.

FIG. 11 is a diagram showing the configuration of the second related art described in Patent Literature 2.

### DESCRIPTION OF REFERENCE NUMERALS

1: optical waveguide board

2: optical waveguide

2a: lower clad layer

2b: upper clad layer

3: optical waveguide core

4: dummy optical waveguide

5: cores of dummy optical waveguide

6, 26, 42: surface electric wiring

7, 27, 41: base material

9, 29, 43: wiring board

10, 11, 21, 22, 46, 47: opening

12: light receiving element

13: light receiving region

14, 48: bumps

15: resin

16, 53: board mark

17: optical axis of core of optical waveguide

18: center of opening

31: optical waveguide board

32: fiber V groove

33: alignment V groove

34: optical fiber

44: light emitting element

45: light emitting region

51: board

52, 53: through hole

101: optical module

102: light receiving/emitting element

103: optical waveguide board

104: signal core

105: position regulating core

106: alignment mark

121: light receiving/emitting part

130: end face

202: chip part (wiring board)

202a: image pattern (pin hole)

203: mount board (optical waveguide board)

203b: connecting surface

203c: positioning target (input/output end of optical waveguide)

207: camera A

208: camera B

210: camera C

P: other end

δy: offset amount

### BEST MODE FOR CARRYING OUT THE INVENTION

According to the present invention, at the time of optically coupling an optical element, such as a light receiving element and light emitting element, to optical wirings, such as an optical waveguide and an optical fiber, first, the optical element is aligned with an optical path provided on an electric wiring board and mounted on the electric wiring board. Next, a plurality of first positioning shapes provided on the electric wiring board to specify the position of the optical path, and a plurality of second positioning shapes, provided together with the optical wiring on the optical wiring board to specify the position of an end portion of the optical wiring are observed at the same time. Then, the positions of the optical path and the end portion of the optical wiring are calculated from the positions of the observed first and second positioning shapes, and the electric wiring board and the optical wiring board are aligned with each other based on those calculated positions.

The execution of such alignment can allow the optical element and the optical wiring to be indirectly aligned with each other with a high accuracy without executing direct alignment. While the observation of the first and second positioning shapes can be executed using an imaging process, for example, the positioning shapes are observed simultaneously without using reference images, thus eliminating the need for positional compensation based on the imaging conditions or the like. As stated above, an optical element and an optical wiring can be optically coupled together via the optical path by a relatively easy method and with a high accuracy, without requiring a special alignment apparatus. In addition, according to the present invention, adjustment after optical coupling is made can be easily carried out with the optical element mounted, so that alignment can be carried out repeatedly until the alignment accuracy falls within a predetermined allowable range. This can suppress the occurrence of defects.

The feature of the present invention lies in that the positions of the optical path and optical wiring are grasped indirectly using a plurality of positioning shapes which have a predetermined positional relation with the positions of the optical path and optical wiring. Therefore, the first and second positioning shapes can take various shapes, such as a projection, a recess, a through hole, an opening or a mark. Further, the first positioning shape may be a through hole or a window having an opening and a transparent base material, so that the shape of the second positioning shape is observed through the window from the optical element side of the electric wiring board. Such first and second positioning shapes are favorable because when they are formed in the same process as the optical path and optical wiring, their positional relation can be grasped with a higher accuracy.

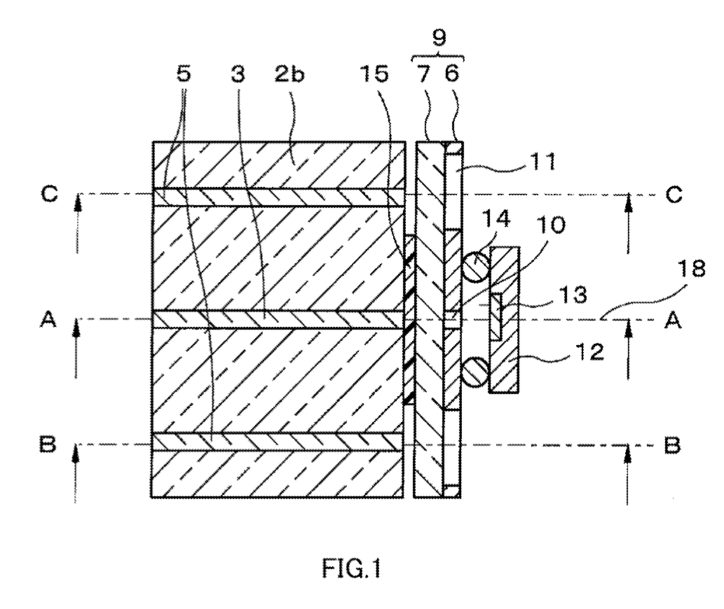

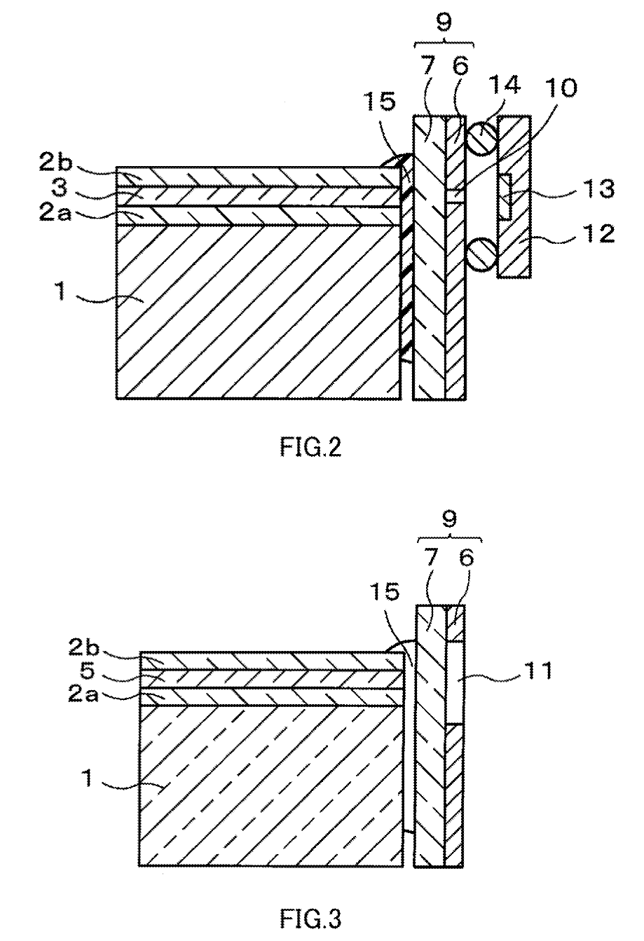

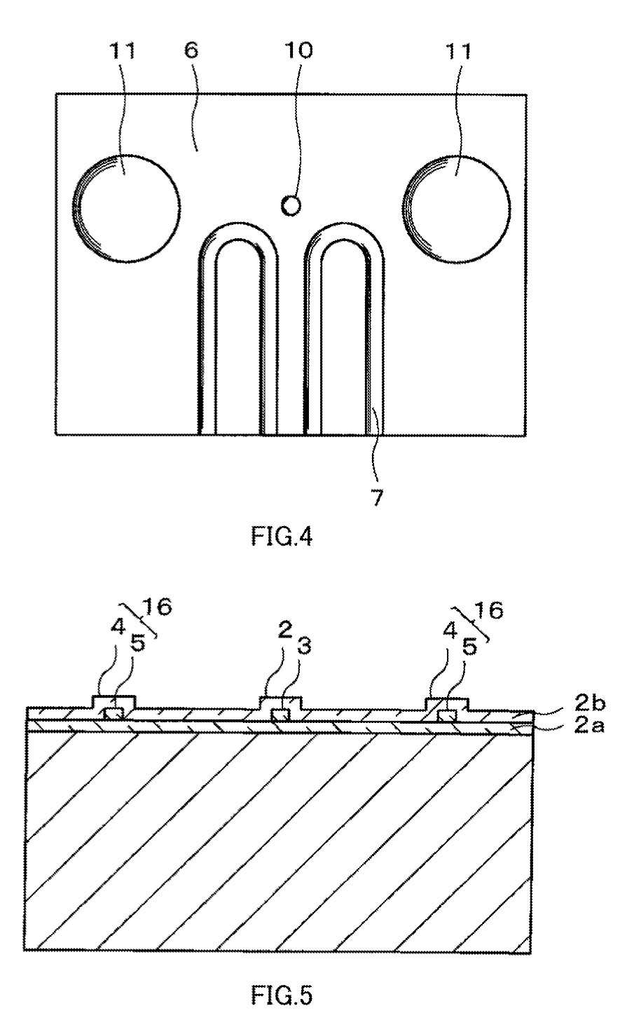

Embodiments of the present invention will be specifically described below with reference to the accompanying drawings. First, the first embodiment will be described. FIG. 1 is a planar cross-sectional view showing an optical module according to the first embodiment, cut at a plane passing the optical axis of the core of an optical waveguide. FIG. 2 is a longitudinal cross-sectional view along line A-A shown in FIG. 1, and FIG. 3 is a longitudinal cross-sectional view along line B-B shown in FIG. 1. It is to be noted that a longitudinal cross-sectional view along line C-C in FIG. 1 is substantially the same as FIG. 3 except that a resin 15 is not seen. FIG. 4 is a diagram showing the electrode pattern of a wiring board 9. FIG. 5 is a side cross-sectional view of an optical waveguide board as viewed from that side where the wiring board 9 is fixed.

As shown in FIG. 1, in the optical module according to the embodiment, a light receiving element 12 having a light receiving region 13 is optically coupled to an optical waveguide having an optical waveguide core 3. Cores 5 of two dummy optical waveguides are arranged on both sides of the optical waveguide core 3. A lower clad layer 2a is formed on an optical waveguide board 1, the cores 3, 5 are formed on the lower clad layer 2a, and an upper clad layer 2b is formed above the lower clad layer 2a with the cores 3, 5 sandwiched therebetween. The optical waveguide core 3 constitutes a part of an optical waveguide 2, and the dummy optical waveguide core 5 constitutes a part of a dummy optical waveguide 4. The dummy optical waveguides 4 and the dummy optical waveguide cores 5 serve as board marks 16 in alignment to be described later.

The wiring board 9 is provided between the optical waveguide core 3 and the light receiving element 12. The wiring board 9 has a surface electric wiring 6 and a base material 7. A metal, such as copper, can be used for the surface electric wiring 6. The light receiving element 12 of the surface input type is mounted on the surface electric wiring 6 in a flip-chip manner by bumps 14. As shown in FIG. 4, the wiring board 9 has an electrode formed by the surface electric wiring 6 and the base material 7 and defined by, for example, an U-shaped groove, and the light receiving element 12 is electrically connected to the electrode. Gold stud bumps, for example, can be used as the bumps 14.

As shown in FIGS. 1 to 4, the surface electric wiring 6 has an opening 10 larger than the cross section of the optical waveguide core 3 at the position thereof, and has two openings 11 larger than the cross sections of the dummy optical waveguide cores 5 at the positions thereof. While various materials can be used for the base material 7, a material having light transmission, e.g., a transparent material like glass, is used in the embodiment. Accordingly, the dummy optical waveguides 4 and the dummy optical waveguide cores 5 can be observed through the openings 11 from the side of light receiving element 12 of the wiring board 9. The base material 7 and the optical waveguide board 1 are fixed by the resin 15.

The light receiving element 12 has the light receiving region 13 provided at the position facing the opening 10 provided in the surface electric wiring 6. Because the base material 7 has a light transmission according to the embodiment, as mentioned above, the opening 10 and the base material 7 constitute an optical path through which the optical waveguide having the optical waveguide core 3 and the light receiving element 12 are optically coupled together.

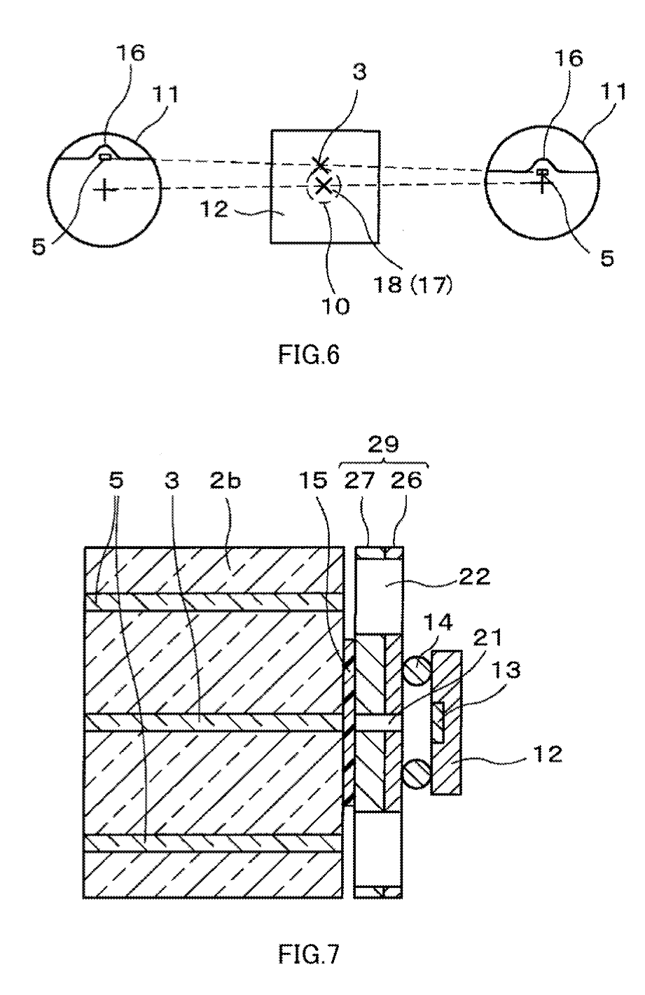

Next, of the optical module manufacturing method according to the embodiment, particularly, a method of aligning the optical waveguide with the light receiving element will be described referring to FIG. 6. FIG. 6 is a diagram showing the two openings 11 provided in the surface electric wiring 6 from the side of the light receiving element 12.

First, the light receiving element 12 is mounted on the wiring board 9 in a flip-chip manner using the bumps 14. The thickness of the wiring board 9 is, for example, 50 μm. At this time, given that the light receiving element 12 is disposed on the surface electric wiring 6 side, the opening 10 and the light receiving region 13 are aligned with each other from the base material 7 side. The size of the light receiving region 13 is, for example, 50 μm in diameter, and the size of the opening 10 is, for example, 30 μm in diameter, and the bumps 14 have a height of, for example, about 20 μm. According to the embodiment, because a transparent material is used for the base material 7 as mentioned above, alignment can be carried out easily. The alignment accuracy should be such an error that the opening 10 falls within the range of the light receiving region 13, and is, for example, ±10 μm according to the embodiment.

Next, the optical waveguide core 3 and the opening 10 are aligned with each other. Here, the images of the two openings 11 provided on both sides of the opening 10, and the board marks 16 through the openings 11 are picked up as the same image from the light receiving element 12 side by an unillustrated imaging apparatus. The board marks 16 are respectively observed in the two openings 11 on the image. It is to be noted that the size of the openings 11 is, for example, 100 μm in diameter. According to the embodiment, the center of the line connecting the cores 5 in the board mark 16 comes to the position of the core 3 of the optical waveguide 2. Here, because the core 3 of the optical waveguide 2 and the cores 5 of the dummy optical waveguides 4 are formed on the lower clad layer 2a in the same process, the optical waveguide core 3 and the two dummy optical waveguide cores 5 can be formed with a high accuracy to have predetermined distances, respectively.

According to the embodiment, the position of the opening 10 is set to the center of the line connecting the center positions of the two openings 11. Here, because the opening 10 and the openings 11 on both sides thereof are formed in the same process at the time of forming the surface electric wiring 6, they can be formed with a high accuracy to have predetermined distances between their centers. In this manner, the positions are adjusted in such a way that deviations of the center positions of the optical waveguide core 3 and the opening 10, which are calculated in the image processing or the like, lie within an allowable range. According to the embodiment, they are set to, for example, ±5 μm. Thereafter, the optical waveguide board 1 and the wiring board 9 are fixed by the resin 15. This provides the optical module according to the embodiment.

Next, the manufacturing method for the optical module according to the embodiment will be described. According to the embodiment, alignment of the optical waveguide core 3 with the opening 10 is executed using the board marks 16 and the openings 11. The board marks 16 should have the positional relation between the optical waveguide 2 and the optical waveguide core 3 set beforehand. According to the embodiment, the board marks 16 are formed in the same process as the optical waveguide 2 and the core 3 of the optical waveguide 2, so that they are formed with a very high accuracy in connection with the optical waveguide 2 and the optical waveguide core 3, which is more favorable. If the positional relation of the openings 11 with the opening 10 is set beforehand, it is possible to specify the position of the opening 10. According to the embodiment, because the openings 11 are formed in the same process as the opening 10, the openings 11 likewise are formed with a very high accuracy with respect to the opening 10. Therefore, the center 18 of the opening 10 and the optical axis 17 of the optical waveguide 2 can be calculated with a high accuracy from the acquired images of the openings 11 and the board marks 16. That is, the opening 10 and the optical waveguide 2 can be aligned with each other indirectly without directly observation of the opening 10 and the optical waveguide 2.

Because the alignment can be repeated with the alignment accuracy being checked until the misalignment falls within the allowable range, defective alignment is suppressed at the alignment process. Accordingly, expensive optical waveguide boards can be used effectively without being wasted. At this time, two sets of the openings 11 and the board marks 16 are simultaneously acquired as the same image, so that unlike in the case of separating providing reference images, an imaging-condition oriented error does not occur. Further, because the accuracy can be checked even after the fixation, information on the misalignment in the fixing step can be used as a mounting offset in next or later alignments. Because alignment of an optical module can be carried out easily without requiring a special alignment apparatus, providing an optical module excellent in mass productivity.

Further, because the light receiving region 13 of the light receiving element 12 includes the entire area of the opening 10 for signal passage according to the embodiment, the whole signal light which has passed through the opening 10 enters the light receiving element 12. Therefore, it is sufficient to have a highly accurate positional relation between the opening 10 for signal passage and the optical waveguide, reducing the steps that demand severe precision.

As described above, the embodiment can provide an optical module which can be mounted and assembled easily with a high accuracy and is excellent in mass productivity, and a method of manufacturing the same.

Next, the second embodiment will be described referring to FIG. 7. FIG. 7 is a planar cross-sectional view showing an optical module according to the second embodiment, cut at a plane passing the optical axis of the core of an optical waveguide. Same reference numerals are given to those components which are the same as the corresponding components of the first embodiment shown in FIG. 1, omitting their detailed descriptions.

As shown in FIG. 7, the optical module according to the embodiment includes a wiring board 29 having a surface electric wiring 26 and a base material 27. An opaque material is used for the base material 27 in the components. The surface electric wiring 26 and base material 27 have an opening 21 of, for example, 30 μm in diameter larger than the cross section of the core 3 at the position of the optical waveguide core 3, and have openings 22 of, for example, 100 μm in diameter larger than the cross section of the cores 5 at the positions of the dummy optical waveguide cores 5. The structure other than the above is the same as that of the first embodiment shown in FIG. 1.

With the configuration of the embodiment, even when a base material other than glass or the like is favorable in consideration of the characteristic of the electric wiring board, an effect similar to that of the first embodiment is obtained.

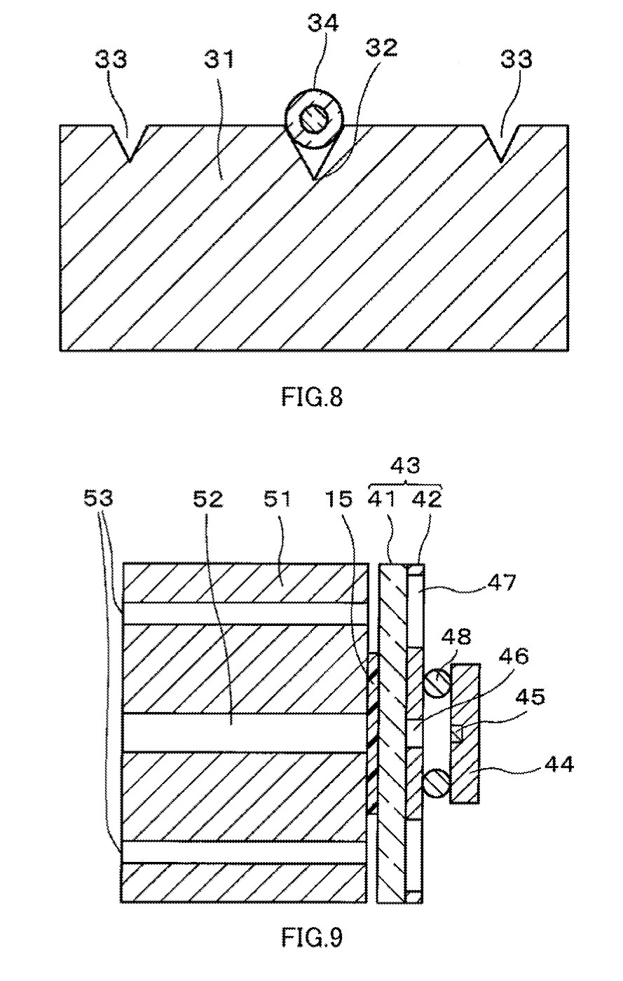

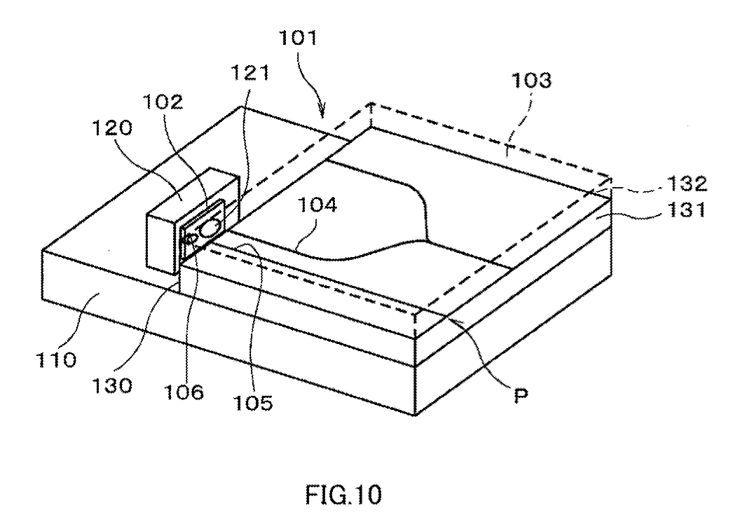

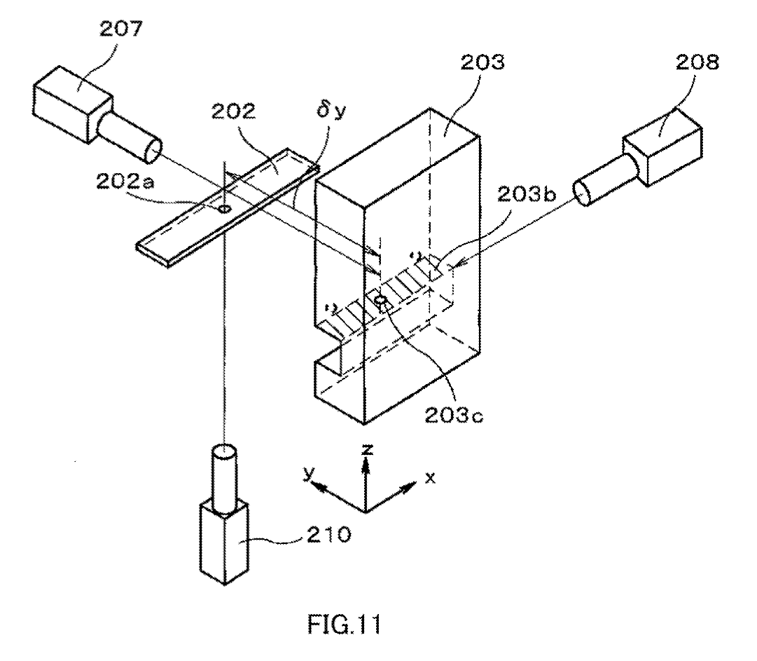

Next, the third embodiment will be described referring to FIG. 8. An optical module according to the embodiment has an optical fiber and a light receiving element optically coupled together by way of example. FIG. 8 is a diagram showing an optical waveguide board of the optical module according to the third embodiment, and corresponding to FIG. 5.

As shown in FIG. 8, an optical fiber 34 is provided at a position equivalent to the optical waveguide core 3. This optical fiber 34 is positioned and fixed in a fiber V groove 32 provided in an optical waveguide board 31. Two alignment V grooves 33 are provided at positions equivalent to the board marks 16 in FIG. 5. The structure other than the above is the same as that of the first or second embodiment.

According to the embodiment, the fiber V groove 32 and the alignment V grooves 33 are formed in the optical waveguide board 31. Because those V grooves can be formed by, for example, anisotropic etching, and are formed in the same process with the same mask, the positional accuracy is considerably high in addition, because the optical fiber 34 is fitted and positioned in the fiber V groove 32, the position of the core of the optical fiber 34 is acquired accurately in connection with the fiber V groove 32. As in the method described in the description of the first embodiment, therefore, the position of the core of the optical fiber 34 can be calculated from the positions of the alignment V grooves 33 (board marks) with a considerably high accuracy.

Next, the fourth embodiment will be described referring to FIG. 9. An optical module according to the embodiment has an optical fiber and a light emitting element optically coupled together by way of example. FIG. 9 is a planar cross-sectional view showing an optical module according to the fourth embodiment, cut at a plane passing the optical axis of the optical axis of the light emitting element.

As shown in FIG. 9, a light emitting element 44 having a light emitting region 45 is mounted on a wiring board 43 having a base material 41 and a surface electric wiring 42 using bumps 48. The base material 41 is formed of a transparent material, such as glass. The surface electric wiring 42 has an opening 46 to be aligned with the light emitting region 45, and two openings 47 on both sides thereof. The above structure is the same as that of the first embodiment shown in FIG. 1, except for the difference between the light receiving element and the light emitting element. It is to be noted that in case of the light emitting element 44, it is favorable that the size of the opening 46 is larger than that of the light emitting region 45. According to the embodiment, the light emitting element 44 has the light emitting region 45 of, for example, 10 μm in diameter, and the opening 46 of, for example, 50 μm in diameter. The size of the opening 46 is smaller than the size of the cross section of the core of the optical fiber (not shown). The accuracy of mounting the light emitting element 44 on the wiring board 43 should be such an error that the light emitting region 45 falls within the range of the opening 46, and is, for example, ±20 μm according to the embodiment.

As shown in FIG. 9, a through hole 52 is provided in a board 51, and two through holes 53 are provided on both sides thereof. Of the through holes, the through hole 52 is a hole through which the optical axis of the light emitting element 44 passes, and the light emitting element 44 is optically coupled to the optical fiber through the hole. The through holes 53 also serve as board marks for positioning. That side of the board 51 where one opening of the through hole 52 is provided, and the base material 41 are fixed by the resin 15.

According to the embodiment, the board marks are formed as the through holes 53. Because the through hole 52 and through holes 53 are formed in the board 51 in the same process, the through holes can be formed with a very high accuracy. Therefore, alignment can be carried out with the method illustrated in FIG. 6 as per the foregoing individual embodiments. According to the embodiment, the optical waveguide core 3 in FIG. 6 is equivalent to the center of the through hole 52, and the dummy optical waveguide cores 5 are equivalent to the centers of the through holes 53. This makes it possible to correctly align the light emitting region 45 of the light emitting element 44 with the through hole 52. Further, if the misalignment of the opening 46 with the light emitting region 45 at the time of mounting the light emitting element 44 on the wiring board 43 is compensated to align the board marks (through holes 53) with the openings 47, application to an optical waveguide or a single mode optical fiber or the like which has a small core diameter.

In addition, when the light emitting element is configured in such a way that the light emitting region 45 of the light emitting element 44 is entirely included in the opening 46 for signal passage, the positional relation between the opening 46 for signal passage and the optical fiber should have a high accuracy as in the light receiving element, thus reducing the steps that demand severe precision. The present embodiment employs an optical fiber that serves as the optical wiring. However, the same description as the above applies when an optical waveguide is used.

It is to be noted that although the positioning shapes for specifying the positions of an optical path and an optical wiring (e.g., optical waveguide or optical fiber) are an opening, V groove and through hole in each of the foregoing embodiments by way of example, the invention is not limited to this case. The intention of the invention is to indirectly grasp the positions of an optical path and optical wiring using a plurality of positioning shapes whose relation with those positions are predetermined. Therefore, the positioning shapes provided on the electric wiring board or optical waveguide board may be a projection other than the optical waveguide, or a recess other than the V groove, and a mark for recognition pattern or the like may be formed on the observation surface.

According to each of the foregoing embodiments, the positioning shape formed on the electric wiring board is a through hole or a window having an opening and a transparent base material. Although the shape of the positioning shape is observed through the window from the optical element side of the electric wiring board, the invention is not limited to this case. While the individual foregoing embodiments are favorable in that the optical waveguide board can be structured compact, a plurality of dummy optical waveguides formed on the optical waveguide board may be arranged at positions, such as outside the electric wiring board, which are not blocked by the electric wiring board at the time of observation.

This application claims the priority of Japanese Patent Application No. 2007-157851 filed on Jun. 14, 2007, which is incorporated herein by reference in its entirety.

### INDUSTRIAL APPLICABILITY

The optical module according to the invention and the method of manufacturing the same can indirectly align an optical element, such as a light receiving element and a light emitting element, and an optical wiring, such as an optical waveguide and an optical fiber, with each other with a high accuracy without directly aligning the optical element with the optical wiring at the time of optically coupling to the optical element to the optical wiring.

1. An optical module comprising:
an electric wiring board on which an optical path is formed;
an optical element mounted on the electric wiring board; and
an optical wiring board having an optical wiring optically coupled to the optical element via the optical path, wherein
the electric wiring board has a plurality of first positioning shapes for specifying a position of the optical path,
the optical wiring board has a plurality of second positioning shapes for specifying a position of an end portion of the optical wiring, and
the first and second positioning shapes are observable at a same time.

2. The optical module according to claim 1, wherein the first positioning shapes include a projection, a recess, a through hole, an opening or a mark formed on the electric wiring board.

3. The optical module according to claim 2, wherein the electric wiring board having the opening formed thereon has a light transmitting base material.

4. The optical module according to claim 2, wherein the optical path has a through hole or an opening that is different from the first positioning shapes and formed in a same process as the process that forms the first positioning shapes.

5. The optical module according to claim 2, wherein the second positioning shapes are observable through the through hole or the opening constituting the first positioning shapes from a side of the optical element on the electric wiring board.

6. The optical module according to claim 1, wherein the second positioning shapes include a projection, a recess, a through hole, an opening or a mark formed on the optical wiring board.

7. The optical module according to claim 6, wherein the optical wiring has a projection, a recess or a through hole that is different from the second positioning shapes formed in a same process as the process that forms the second positioning shapes.

8. The optical module according to claim 7, wherein the projection of the second positioning shapes is a dummy optical waveguide, and the projection of the optical wiring is an optical waveguide for a signal.

9. The optical module according to claim 7, wherein the recess of the second positioning shapes is a positioning V-shaped groove, and the recess of the optical wiring is a V-shaped groove for an optical fiber for fixing an optical fiber.

10. The optical module according to claim 1, wherein the optical element is a light receiving element.

11. The optical module according to claim 1, wherein the optical element is a light emitting element.

12. A method of manufacturing an optical module comprising the steps of:
mounting an optical element on an electric wiring board in alignment with an optical path formed on the electric wiring board;
simultaneously observing a plurality of first positioning shapes formed on the electric wiring board and a plurality of second positioning shapes formed on an optical wiring board, with an optical wiring having the optical wiring and the electric wiring board overlapping each other;
calculating a position of the optical path from positions of the observed first positioning shapes, and calculating a position of an end portion of the optical wiring from positions of the second positioning shapes; and
fixing the electric wiring board and the optical wiring board in alignment with each other based on the calculated position of the optical path and the calculated position of the end portion of the optical wiring in such a way as to optically couple the optical element and the optical wiring board via the optical path.

13. The method according to claim 12, wherein the first positioning shapes include a projection, a recess, a through hole, an opening or a mark formed on the electric wiring board.

14. The method according to claim 13, wherein the through hole or opening constituting the first positioning shapes, and a through hole or an opening constituting the optical path are formed on the electric wiring board in a same process.

15. The method according to claim 13, wherein the second positioning shapes are observed through the through hole or the opening constituting the first positioning shapes from a side of the optical element on the electric wiring board.

16. The method according to claim 12, wherein the second positioning shapes include a projection, a recess, a through hole, an opening or a mark formed on the optical wiring board.

17. The method according to claim 16, wherein the projection, recess or through hole constituting the second positioning shapes, and a projection, recess or through hole constituting the optical wiring are formed on the optical wiring board in a same process.

18. The method according to claim 17, wherein the projection of the second positioning shapes is a dummy optical waveguide, and the projection of the optical wiring is an optical waveguide for a signal.

19. The method according to claim 17, wherein the recess of the second positioning shapes is a positioning V-shaped groove, and the recess of the optical wiring is a V-shaped groove for an optical fiber for fixing an optical fiber.

20. The method according to claim 12, wherein the optical element is a light receiving element, and the optical element and the optical path are aligned with each other in such a way that a light receiving region of the optical element includes an entire cross-sectional area of the optical path.

21. (canceled)
